(19) United States
(12) Patent Application Publication
(10) Pub. No.: US 2003/0201463 A1
(43) Pub. Date: Oct. 30, 2003

(54) Automatic layout and wiring method for semiconductor integrated circuit

(76) Inventors: Nobuyuki Ikeda, Tokyo (JP); Kazuhiro Takahashi, Tokyo (JP)

Correspondence Address: BURNS, DOANE, SWECKER & MATHIS, L.L.P., P.O. Box 1404, Alexandria, VA, 22313-1404, US

(21) Appl. No.: 10/272,909

(22) Filed: Oct. 18, 2002

(30) Foreign Application Priority Data
Apr. 26, 2002 (JP) 2002-125508

(51) Int. Cl. H01L 31/0328

(52) U.S. Cl. 257/200

(57) ABSTRACT

A net including paths having a long inter-path distance is designated as one to which a specific design rule for defining a wide wire and a wide wiring interval is applied. After the designation, optimization of a circuit such as a change in cell drivability and insertion of a driver cell is performed so as to satisfy a timing condition designated by timing restriction information.

### BACKGROUND OF THE INVENTION

1) Field of the Invention

The present invention relates to a technology for conducting automatic layout and wiring of a semiconductor integrated circuit.

2) Description of the Related Art

A conventional semiconductor integrated circuit such as a cell base includes logical circuits such as AND circuits and OR circuit, state holding circuits such as flipflops and latch circuits, or memory circuits arranged in its internal area. These circuits are wired to each other based on connection information to thereby realize desired functions.

In recent years, with the improvement on micropatterning technique of semiconductor manufacture, a mount gate scale of one chip increases, and a high-performance and high-function LSI can be realized by one chip. On the other hand, with a decrease in wiring width, a wiring capacity increases. When a wiring length increases, delay of signals and round pulses cause problems.

In order to solve the above problems, an automatic layout and wiring method for a semiconductor integrated circuit is considered such that the wiring width of a path having a long wiring length is increased to reduce a wiring load and to suppress a delay time of a signal. More specifically, in order to reduce the wiring load of a path having a wide wiring interval, wiring is performed based on a specific design rule for defining a wide wire and a wide wiring interval (“specific design rule”) different from a regular design rule. The specific design rule uses a wiring layer on which wiring is performed with a wire width and a wiring interval different from those in the regular design rule.

FIG. 5 shows a conventional timing-controlled automatic layout and wiring program. In FIG. 5, reference numeral 200 denotes an LSI circuit connection information, 201 denotes timing restriction information, 202 denotes a design rule, and 203 denotes a timing control automatic layout and wiring program.

The program 203 includes instructions for conducting layout and wiring of a circuit defined by the LSI circuit connection information 200 based on the timing restriction information 201 and the design rule 202.

In an arranging step, cells (logical circuits, state holding circuits, or memory circuits) defined by the LSI circuit connection information 200 are arranged (step S300). In a wiring load extracting step, a length of wiring for a connection signal is estimated from the information of the arranged cells and the LSI circuit connection information and a wiring lord is estimated (step S310). In a circuit optimizing step, based on the estimated result, the optimization of circuits such as a change in cell drivability or insertion of a driver cell is executed so as to satisfy the designated timing (step S320). In a delay analyzing step, initial wiring is executed, and delay analysis for a path is executed (step S330). In a timing verifying step, a path which violates the designated timing from the obtained path analysis result is extracted (step S340). In a wiring net designating step, a path which violates the designated timing detected in the timing verifying step is designated as a path to which the specific design rule is applied (step S350). In a detailed wiring step, final detailed wiring of a net defined by the LSI circuit connection information 200 is so executed that the specific design rule is applied to the designated path and that a regular design rule is applied to other paths (step S360).

As described above, in the conventional timing control automatic layout and wiring program, cells are arranged and circuits are optimized, and then delay analysis is performed and the specific design rule is designated for a path which violates the timing restriction to execute wiring, thereby executing timing adjustment layout.

However, in the conventional automatic layout and wiring program, circuits are optimized based on a design rule used before the specific design rule is designated, i.e., based on a regular design rule. For this reason, a wiring load of a path is larger than a wiring load estimated based on the specific design rule, and a change in cell drivability (in this case, the drivability is changed into a high drivability) and insertion of a driver cell are performed. Therefore, the circuit scale of a semiconductor integrated circuit increases disadvantageously.

The wiring load is estimated based on the regular design rule, and the specific design rule is applied to a path which violates the timing restriction as a result of estimation. For this reason, timing violation is extracted with a heavy load, and the number of paths, designated as ones to which the specific design rule is applied, increases to cause wiring to be impossible. The term of development of a semiconductor integrated circuit is extended disadvantageously.

### SUMMARY OF THE INVENTION

It is an object of this invention to provide an automatic layout and wiring method for a semiconductor integrated circuit capable of conducting layout and wiring based on a design rule suitable for a wiring net by designating the net as one to which wiring using a wide wire and a wide wiring interval is applied and setting a wiring interval, a width of a wire, and a wiring layer, and then by performing optimization of the circuit in which cells are arranged.

The automatic layout and wiring method according to one aspect of this invention, includes steps of arranging a plurality of cells included in LSI circuit connection information in a wiring area based on timing restriction information and a design rule, and extracting a wiring distance between signal paths connected to the arranged cells as state holding circuits. The method also includes designating a wiring net to which a specific design rule is applied based on the extracted inter-path distance, extracting loads of wires based on the inter-path distance and the design rule for the designated wiring net, changing a cell group in the path into an optimum circuit based on the wiring load of the signal path between the state holding circuits, and conducting detailed wiring of the signal wires in the optimized cell group based on the design rule.

These and other objects, features and advantages of the present invention are specifically set forth in or will become apparent from the following detailed descriptions of the invention when read in conjunction with the accompanying drawings.

### BRIEF DESCRIPTION OF THE DRAWINGS

FIG. 1 is a flowchart of an automatic layout and wiring program for a semiconductor integrated circuit according to a first embodiment of this invention,

FIG. 2 is a diagram for explaining a method of extracting an inter-path distance,

FIG. 3 is a flow chart showing the details of the detailed wiring step shown in FIG. 1,

FIG. 4 is a flow chart of an automatic layout and wiring program for a semiconductor integrated circuit according to a second embodiment of this invention, and

FIG. 5 is a flow chart for explaining an operation of the conventional timing control automatic layout and wiring apparatus.

### DETAILED DESCRIPTION

Embodiments of the automatic layout and wiring method according to the present invention will be described below in detail with reference to the accompanying drawings.

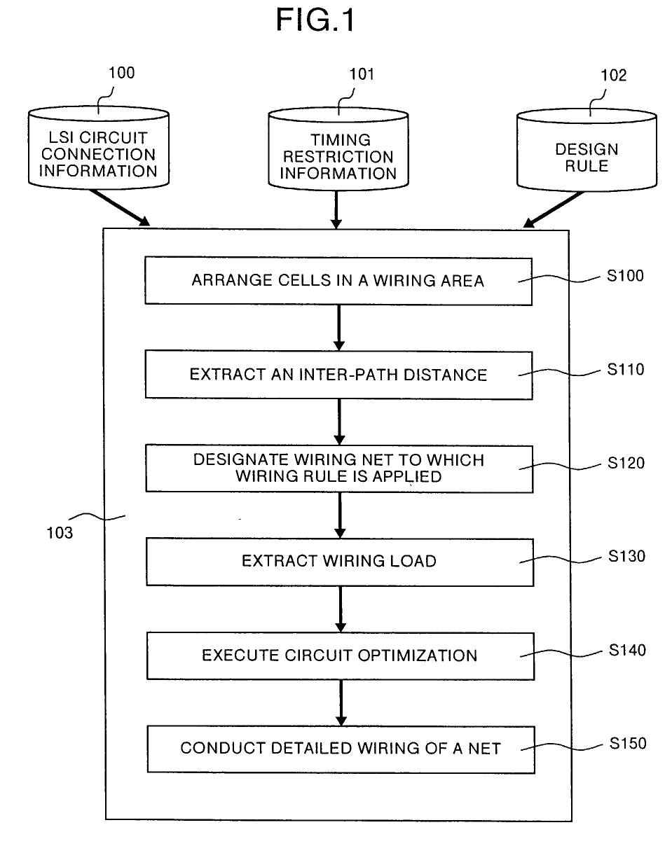

A first embodiment of the present invention will be described below with reference to FIGS. 1 to 3. FIG. 1 shows an automatic layout and wiring program for a semiconductor integrated circuit according to the first embodiment. In FIG. 1, reference numeral 100 denotes LSI circuit connection information which is cell connection information used to realize a desired function of a semiconductor integrated circuit, 101 denotes timing restriction information in which a restriction condition of a delay time between arbitrary cells or arbitrary paths is designated, 102 denotes a design rule related to a process of realizing a semiconductor integrated circuit, and 103 denotes an automatic layout and wiring program for a semiconductor integrated circuit.

The program 103 includes performing arranging and wiring of a circuit defined by the LSI circuit connection information 100 according to the timing restriction information 101 and the design rule 102.

In an arranging step, cells defined by the LSI circuit connection information 100 are arranged in a wiring area in a chip based on the timing restriction information 101 and the design rule 102 (step S100). For example, cells in a path having a timing which is restricted by the timing restriction information 101 are arranged to be close to each other.

Upon completion of the arranging step, in an inter-path distance extracting step, a distance (inter-path distance) from a start point to an end point of a path between two state holding circuits is extracted from an arrangement result obtained in the arranging step (step S110).

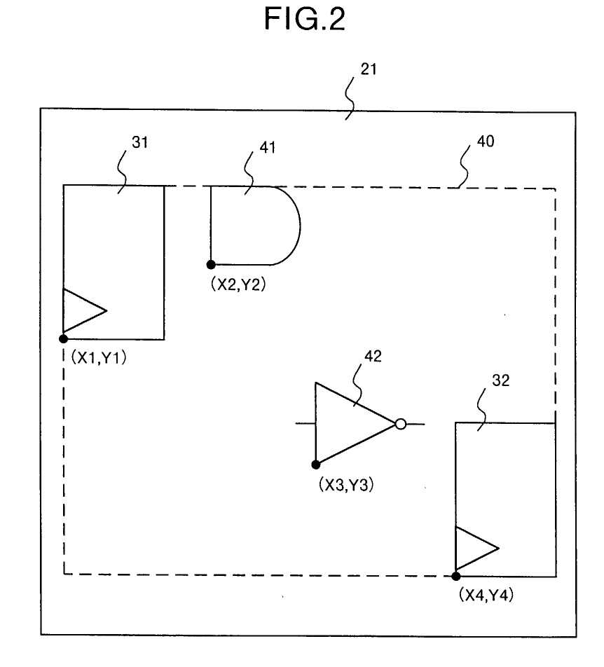

A method of extracting an inter-path distance will be described below with reference to FIG. 2. FIG. 2 shows a state in which a flipflop 31 is arranged at a point (X1, Y1), an AND circuit 41 is arranged at a point (X2, Y2), an inverter 42 is arranged at a point (X3, Y3), and a flipflop 32 is arranged at a point (X4, Y4) in a wiring area 21 in the arranging step. It is assumed that, according to the LSI circuit connection information 100, the output terminal of the flipflop 31 is connected to the input terminal of the AND circuit 41, and the output terminal of the AND circuit 41 is connected to the input terminal of the inverter 42, and the output terminal of the inverter 42 is connected to the input terminal of the flipflop 32. At this time, a minimum square 40 including the four cells is calculated from the arranged positions and the sizes of the cells, and a half of the length of all the sides of the minimum square 40 is set to be an inter-path distance from the flipflop 31 to the flipflop 32.

In an inter-path distance extracting step, inter-path distances of the arranged cells are calculated, data of the paths are sequentially stored in the descending order of the calculated inter-path distances. The entire wire length of the calculated inter-path distance (information for inter-path distance entire wire length) is stored.

Upon completion of the inter-path distance extracting step, in a wiring net designating step, a wiring net of the LSI circuit connection information 100 including the calculated long inter-path distance is designated as a wiring net to which a wiring rule is preferentially applied (step S120). In the wiring rule, at least each one of wire widths, wiring intervals, and wiring layers is defined in advance, and each one of these is selected depending on the inter-path distance. The wiring rule is designated in the following manner. That is, occupancy rates of wiring grids of respective wiring layers including the net designated as one to which the wiring rule is applied, is calculated from information for the number of wiring grids of wiring layers and entire wiring grid line length in a regular design rule, information for the number of wiring grids and entire wiring grid line length in a specific design rule for defining a wide wire and a wide wiring interval (“specific design rule”)), and from information for the inter-path distance entire wiring length calculated in the inter-path distance calculating step. The designation is then performed on nets the number as many as possible within a range in which the calculated occupancy rates of the wire grids do not exceed a numeral value designated in advance. In addition, in the timing restriction information 101, even though the calculated inter-path distance is long, the specific design rule is not applied to a path the timing of which is not restricted.

Upon completion of the wiring net designating step, in a wiring load extracting step, a circuit load is estimated from the calculated inter-path distance and the applied design rule (step S130). At this time, in the wiring net designating step, a path, designated as one to which the specific design rule is applied, has a wiring load which is smaller than that of the regular design rule.

Upon completion of the wiring load extracting step, in a circuit optimizing step, timing is verified based on the estimated wiring load, circuit optimization such as a change in cell drivability and insertion of a driver cell is executed such that the timing condition designated by the timing restriction information 201 is satisfied (step S140).

Upon completion of the circuit optimizing step, in a detailed wiring step, the specific design rule is applied to the path designated as one to which the specific design rule is applied, and the final detailed wiring for the net defined in the LSI circuit connection information 200 is executed to other paths based on the regular design rule (step S150).

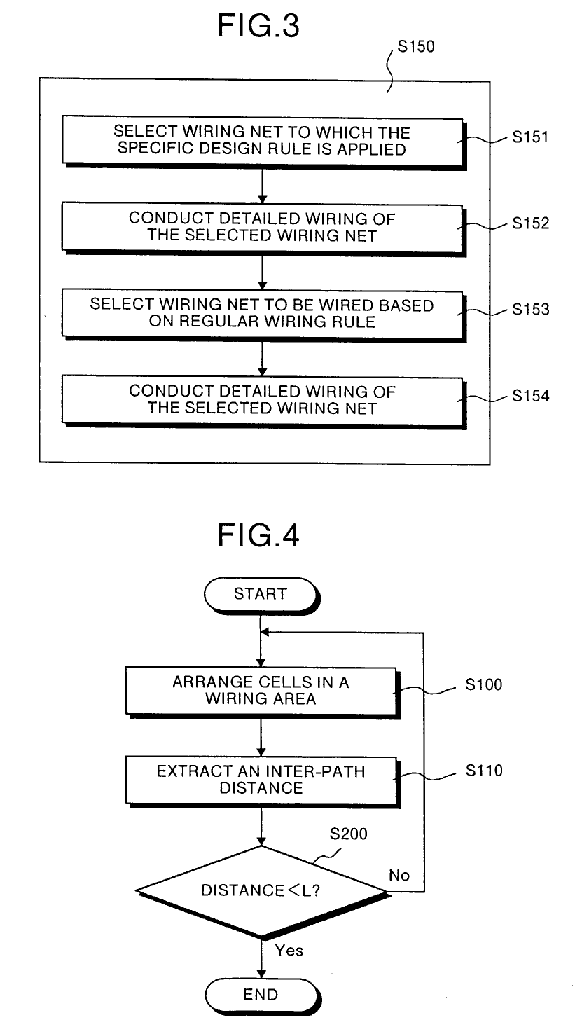

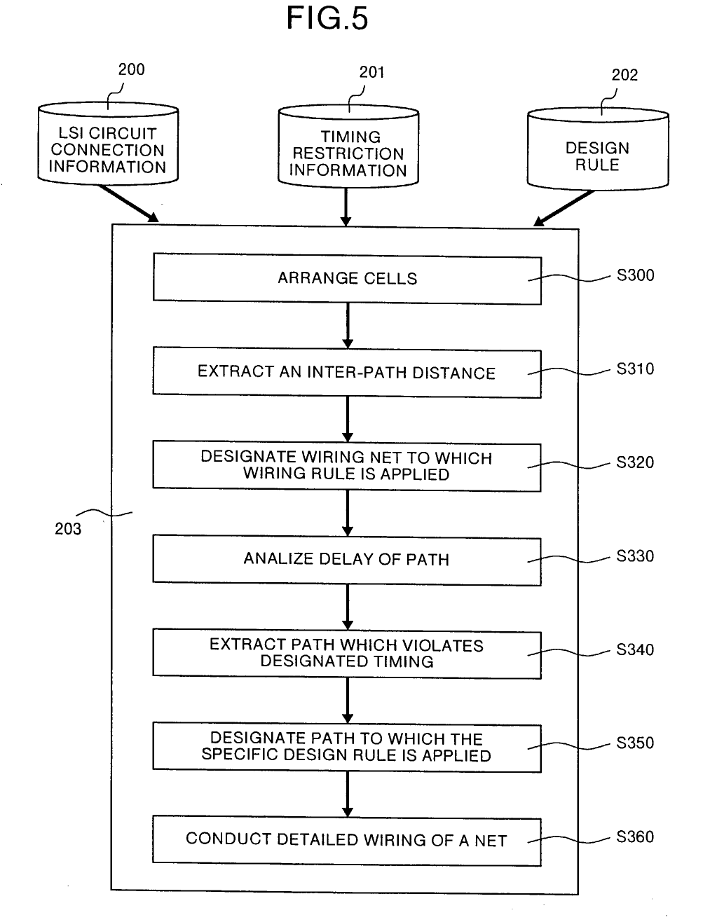

The wiring process of the detailed wiring step will be described below with reference to the flow chart in FIG. 3. In a wiring net selecting step, a wiring net, designated as one to which the specific design rule is applied, is selected (step S151). In a first detailed wiring step, wiring of the selected wiring net, designated as one to which the specific design rule is applied, is executed (step S152). In a regular wiring net selecting step, a wiring net wired based on the regular design rule, except for the wiring net designated as one to which the specific design rule is applied, is selected (step S153). In a second detailed wiring step, the selected wiring net to be wired based on the regular design rule is wired (step S154).

In the detailed wiring step as described above, it is considered that the net designated as one to which the specific design rule is applied has a timing margin smaller than that of the wiring net wired based on the regular design rule. For this reason, a wiring process is executed such that an optimum wiring route is employed to prevent the wire from being bypassed.

As described above, in the first embodiment, there is the circuit optimizing step S140 in which optimization of circuits such as a change in cell drivability and insertion of a driver cell is performed so that the timing condition designated by the timing restriction information 101 is satisfied. Before this step S140, the wiring net designating step S120 is executed so that a net including a path having a long inter-path distance is designated as a net to which the specific design rule is applied. For this reason, the wiring load of the designated net can be estimated based on the design rule. In the circuit optimizing step S140, a cell having excessively high drivability is avoided from being used, and an increase in circuit scale of an LSI can be prevented.

An unnecessary driver cell can be avoided from being inserted, an increase in circuit scale of an LSI can be prevented, and a power consumption can be reduced.

The details of the detailed wiring step is an example of processes. A weighting process is executed to wiring nets for each design rule. For example, the wiring nets designated as ones to which the specific design rule is applied are heavily weighted, and the detailed wiring process may be performed to the wiring nets in the descending order of the weights.

The inter-path distance has been described as a distance from the start point to the end point of a path between two state holding circuits. However, the present invention is not limited to this configuration, a path between two cells may be used.

A second embodiment of the present invention will be described below with reference to FIG. 4. In the first embodiment, in the wiring net designating step S120, a wiring net including the path having a long inter-path distance calculated in the inter-path distance extracting step S110 is designated as a wiring net to which the specific design rule is applied. However, when the number of wiring nets to which the specific design rule is applied, increases, an occupancy rate of wiring grids subjected to detailed wiring increases, and the wires may be concentrated.

In order to solve the above problem, in the second embodiment, in order to control the number of wiring nets designated as ones to which the specific design rule is applied, the decision process S200 of deciding whether the inter-path distance calculated in the inter-path distance extracting step is a predetermined value L or less, is executed between the inter-path distance extracting step S110 and the wiring net designating step S120 of the automatic layout and wiring program according to the first embodiment.

FIG. 4 is a flow chart which explains a method of controlling the number of wiring nets to be designated as ones to which the specific design rule is applied according to the second embodiment.

As in the first embodiment, in the wiring step, cells are arranged in a wiring area (step S100). In the inter-path distance extracting step, an inter-path distance is calculated (step S110). Here, when the inter-path distance is calculated, the calculated inter-path distance is compared with the predetermined value L. When the calculated inter-path distance is larger than the predetermined value L, the cells are arranged again in the arranging step, an inter-path distance is calculated in the inter-path distance extracting step, and comparison with the predetermined value L is repeated (step S200).

As described above, in the second embodiment, when the inter-path distance calculated in the inter-path distance extracting step S110 is larger than the predetermined value L, the arranging step S100 and the inter-path distance extracting step S110 are repeated to make all the inter-path distances be the predetermined value L or less at the last. For this reason, the number of paths designated as ones to which the specific design rule is applied in the wiring net designating step S120 can be controlled, and high-quality automatic layout and wiring which satisfy the timing restriction condition can be executed.

In the arranging step, an automatic layout and wiring operation which satisfy timing restriction can be performed without applying the timing restriction condition. The process time of the arranging step can be shortened.

As described above, according to the automatic layout and wiring method as one aspect of this invention, the method includes steps of arranging a plurality of cells included in LSI circuit connection information in a wiring area based on timing restriction information and a design rule including a specific design rule for defining a wide wire and a wide wiring interval and a regular design rule, extracting an inter-path distance by using a path, as a signal path, used when a signal output from a state holding circuit of the plurality of arranged cells reaches an input of a next state holding circuit, designating a wiring net to which the specific design rule is applied based on the extracted inter-path distance, extracting loads of wires based on the inter-path distance and the design rule for the designated wiring net, changing a cell group in the signal path into an optimum circuit based on the wiring load of the signal path, and conducting wiring based on the designated design rule. For this reason, the wiring load of the designated net can be estimated based on the specific design rule. In the circuit optimizing step, a cell having excessively high drivability is avoided from being used, an increase in circuit scale of an LSI can be prevented, and a power consumption can also be reduced.

Moreover, a wiring net including a signal path having a long inter-path distance is designated as a wiring net to which the specific design rule is preferentially applied. For this reason, it is possible to reduce a wiring load of the wiring net including a path which requires processing other than the circuit optimization, and to facilitate a timing drive layout.

Furthermore, a wiring net including a signal path having timing restriction information in which timing restriction is canceled, is designated as a wiring net to which the specific design rule is not applied. For this reason, the specific design rule is avoided from being applied to a path to which this specific design rule needs not be applied, and is applied only to a path having no margin in a timing restriction condition. Therefore, it is possible to perform a high-quality layout and wiring process.

Moreover, the method includes steps of selecting a wiring net designated as one to which the specific design rule is applied, conducting wiring of the selected wiring net based on the specific design rule, selecting a wiring net wired based on the regular design rule, and conducting wiring of the wiring net based on the regular design rule. For this reason, the wiring net to which the specific design rule is applied can be wired without any bypass, and wiring efficiency can be improved.

Furthermore, a wiring net designated as one to which the specific design rule is applied is heavily weighted based on each specific design rule to conduct wiring of wires in the descending order of weights. For this reason, the wiring nets to which the specific design rule is applied can be wired without any bypass, and wiring efficiency can be improved.

Moreover, a plurality of cells included in LSI circuit connection information are arranged in a wiring area such that an inter-path distance is not more than a predetermined value. For this reason, the number of wiring nets to which the specific design rule is applied is controlled to avoid the wires from being concentrated, and high-quality automatic layout and wiring which satisfy the timing restriction condition can be performed.

Furthermore, a width of a wire and a wiring interval are set based on the information for the inter-path distance designated as one to which the specific design rule is applied. For this reason, any specific design rule suitable for respective inter-path distances can be applied.

Moreover, a grid line length of occupied wiring of each wiring layer is estimated based on the specific design rule with respect to a path designated as one to which this design rule is applied, a grid line length of occupied wiring of each wiring layer is estimated based on the regular design rule with respect to a path designated as one to which the regular design rule is applied, occupancy rates of wiring grids of all the paths are calculated, and a path to which the specific design rule is applied is designated based on the calculated estimated occupancy rates of wiring grids. For this reason, the number of wiring nets to which the specific design rule is applied can be controlled to avoid a wiring impossible state, and a time for designing a semiconductor integrated circuit can be shortened.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. An automatic layout and wiring method for a semiconductor integrated circuit, the method comprising steps of:
arranging a plurality of cells included in LSI circuit connection information in a wiring area based on timing restriction information and a design rule including a specific design rule for defining a wide wire and a wide wiring interval and a regular design rule;
extracting a wiring distance between signal paths connected to the arranged cells as state holding circuits;
designating a wiring net to which the specific design rule is applied based on the extracted inter-path distance;
extracting loads of wires based on the inter-path distance and the design rule for the designated wiring net;
changing a cell group in the path into an optimum circuit based on the wiring load of the signal path between the state holding circuits; and
conducting detailed wiring of the signal wires in the optimized cell group based on the designated design rule.

2. The method according to claim 1, wherein the wiring net designating step includes designating a wiring net, including signal paths having the extracted inter-path distance that is long, to which the specific design rule is preferentially applied.

3. The method according to claim 1, wherein the wiring net designating step includes designating a wiring net, including a signal path in which timing is not restricted in the timing restriction information, to which the specific design rule is not applied.

4. The method according to claim 1, wherein the detailed wiring step includes:
selecting the wiring net designated as one to which the specific design rule is applied;
conducting first detailed wiring of the selected wiring net based on the specific design rule;
selecting a wiring net to be wired based on the regular design rule designated by the design rule; and
conducting second detailed wiring of the selected wiring net based on the regular design rule designated by the design rule.

5. The method according to claim 1, wherein the detailed wiring step includes defining weights to the wires based on a wiring rule, and
the weighting defining step includes setting a heavier weight to a wiring net designated as one to which the specific design rule is applied, based on each specific design rule, and wiring is conducted on the wires in the descending order of the set weights.

6. The method according to claim 1, wherein the arranging step includes arranging a plurality of cells included in the LSI circuit connection information in a wiring area so that the extracted inter-path distance is not more than a predetermined value.

7. The method according to claim 1, wherein the wiring net designating step includes setting a width of a wire and a wiring interval based on the information for the inter-path distance designated as one to which the specific design rule is applied.

8. The method according to claim 1, wherein the wiring net designating step includes:
estimating a grid line length of occupied wiring of each wiring layer based on the specific design rule with respect to a path designated as one to which the specific design rule is applied,
estimating a grid line length of occupied wiring of each wiring layer based on the regular design rule with respect to a path to which the regular design rule is applied,
calculating estimated occupancy rates of wiring grids of all the paths, and
designating a path to which the specific design rule is applied based on the calculated estimated occupancy rates of the wiring grids.
